(19) United States
(12) Patent Application Publication
(10) Pub. No.: US 2024/0061042 A1
(43) Pub. Date: Feb. 22, 2024

(54) Serial Protocol-Based Event Trigger

(71) Applicant: NXP USA, Inc., Austin, TX (US)

(72) Inventors: Tiefei Zang, Austin, TX (US); Pascal Mareau, Grasse (FR); Mathis Deroo, Toulouse (FR); Vincent Bour, Antibes (FR); Edward Allen White, Bee Cave, TX (US); Gang Liu, Suzhou (CN)

(21) Appl. No.: 18/354,961

(22) Filed: Jul. 19, 2023

(30) Foreign Application Priority Data
Aug. 19, 2022 (CN) 202211001352.X

(51) Int. Cl. G01R 31/319; G01R 31/28; G01R 31/317

(52) U.S. Cl. CPC G01R 31/31917; G01R 31/2889; G01R 31/31725

(57) ABSTRACT

A method for a serial protocol-based event trigger includes detecting a condition of a Device Under Test (DUT) with a first text pattern, wherein the condition indicates an enabled function of the DUT. A command is transmitted to the DUT to perform a first action with the enabled function in response to detecting the condition of the DUT. A second text pattern received from the DUT is detected in response to the first action. The second text pattern indicates a successful completion of an event by the enabled function. A second action is performed in response to detecting the second text pattern.

### FIELD

This disclosure relates generally to testing of electronic devices, and more specifically to a serial protocol-based event trigger for predictable and accurate measurements of an electronic Device Under Test (DUT).

### BACKGROUND

Digital electronic systems typically generate events related to changes in states or operating modes. While events may occur asynchronously with respect to a system clock, or a separate monitoring device, such systems still typically require accurate time-based measurement of the occurrence of these events with low latency and without synchronization induced errors. For example, time-based measurements may be used in a testing environment to measure power consumption of a DUT, after the DUT has transitioned to a lower power operating mode.

An event-triggered approach is problematic for testing and validation of a DUT due to the difficulty in predicting asymmetric events over variations in process, voltage and temperature. While a time-triggered approach may provide more predictable results, jitter issues remain and the amount of test data to be processed increases significantly. Additionally, testing with an event-triggered approach typically requires operating restrictions or modifications to the DUT to reduce the complexity and improve determinism of the generated events.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a schematic view of an embodiment of a test system including a serial protocol-based event trigger.

FIG. 2 is a schematic view of an embodiment of a test system for power measurement including a serial protocol-based event trigger.

FIG. 3 is a schematic view of a host-based system for generating a serial protocol-based event trigger, in accordance with an embodiment of the present disclosure.

FIG. 4 is a flowchart representation of a method for a serial protocol-based event trigger, in accordance with an embodiment of the present disclosure.

FIG. 5 is a flowchart representation of another method for a serial protocol-based event trigger, in accordance with an embodiment of the present disclosure.

FIG. 6 is a flowchart representation of another method for a serial protocol-based event trigger, in accordance with an embodiment of the present disclosure.

FIG. 7 is a flowchart representation of another method for a serial protocol-based event trigger, in accordance with an embodiment of the present disclosure.

### DETAILED DESCRIPTION

Embodiments described herein provide for an event trigger module operating and contained exclusively on a host, the module communicating bilaterally with a DUT using a serial protocol (e.g., RS232 or RS485). The event trigger module operates independent of the DUT, without any required changes to the DUT hardware or software, thus providing standalone utility. Communication between the host and the DUT occurs through a readily available serial port of the DUT to determine a condition of the DUT by matching a first pattern of activity from the DUT with a first predefined pattern in the host. The term “pattern” used throughout this disclosure means one or more American Standard Code for Information Exchange (ASCII) text strings including, but not limited to, a text string announcing an acquired functionality or mode of the DUT or an event in response to a first action performed by the acquired functionality or mode. For example a pattern including “storage device detected” may be transmitted by the DUT after the DUT detects the insertion of an external storage device into the DUT. The term “condition” means the acquired functionality or mode. For example, a DUT with a storage device inserted or otherwise coupled thereto, acquires a condition of having a communication path established with the storage device to enable data transfer between the DUT and the storage device. Once a “condition” of the DUT is determined by the host, an “event” may occur, which depends upon the condition. For example, a condition of a storage device coupled to the DUT may be followed by a command for the DUT to perform a first action. The first action may be writing data from the DUT to the storage device. In response to the first action, an event may be a successful transfer of data from the DUT to the storage device.

In various embodiments, the first predefined pattern may by be entered as a text string (e.g., an event command string), as a series of text strings (e.g., a text script file), or as a series of conditional text strings. In one example, the condition of the DUT is a power mode (e.g., active, sleep, deep sleep). In another example, the condition of the DUT relates to a device coupled to the DUT, such as a Universal Serial Bus (USB) storage device or an Ethernet cable. Subsequent to determining the condition of the DUT, the host sends a command to the DUT over the serial port to invoke a response from the DUT specific to the condition. A second pattern is received by the DUT in response to the condition responding to the command. The second pattern is further compared to a second predefined pattern in the host, where the second predefined pattern is entered into the host in one of the methods used to enter the first predefined pattern.

If a successful pattern match is made between the second pattern and the second predefined pattern, then a second action is triggered. In one example where the condition includes coupling or inserting a USB device into the DUT, the second predefined pattern may represent a successful read or write of data between the USB device and the DUT. The second action may include communicating with or initiating an action with another module within the host, the DUT, the test system or a module external to the host, DUT or test system. In an example, where the action includes putting the DUT into a lower power “sleep” mode, the action may include making a supply current measurement of the DUT with a current meter. In another example, the DUT is a smart watch device or circuit, where the current measurement is initiated upon a Global Positioning System (GPS) event of the smart watch. The second action may further include current profiling or trend analysis.

In another example, a timestamp is taken to mark the time the second action, and potentially subsequent second action occurs. In another example, a flag is set in response to the timestamp being taken. Accordingly, embodiments of the event trigger module provide low latency between the occurrence of a DUT event and a measurement or other response to the event (e.g., the latency between the second pattern generated by the DUT and the second action in response thereto). Furthermore, the command sent to the DUT and the second pattern or event detection both occur with the host in a synchronous manner, thus avoiding synchronization induced errors present in previous solutions. In the various embodiments described herein, the term “module” should be construed to include implementations including a hardware circuit, firmware, software or any combination therein.

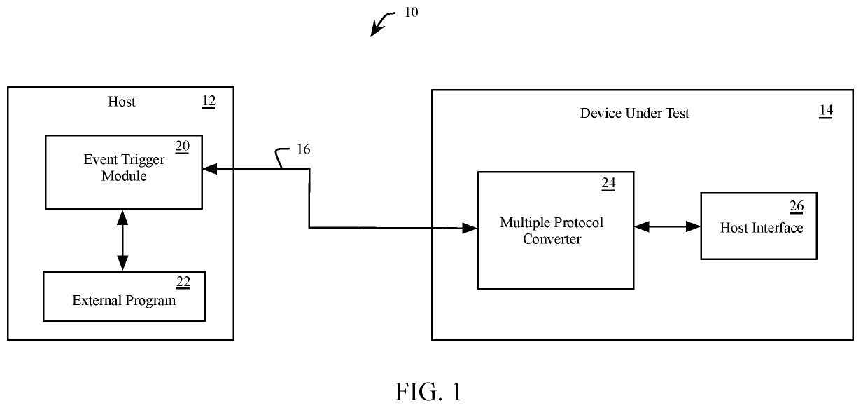

FIG. 1 shows an embodiment 10 of a test system including a serial protocol-based event trigger. A host 12 communicates with a DUT 14 over a serial link 16, connecting respective serial ports of the host 12 and DUT 14. The host 12 includes an event trigger module 20, which communicates bilaterally with the DUT 14 over the serial link 16 and further communicates with an external program 22. Specifically, the event trigger module 20 may detect a first pattern of the DUT 14 received over the serial link 16 to detect a condition of the DUT 14 (e.g., a power mode of the DUT 14, a coupling of a device such as a USB or ethernet cable to the DUT 14 or another condition). The detection of the first pattern may include matching the first pattern to a predefined first pattern stored in the event trigger module 20.

The event trigger module 20 may send a command to the DUT 14 over the serial link 16 to perform a first action (e.g., initiate a read or write between the DUT 14 and the USB, transfer data between the DUT 14 and an ethernet cable, and the like). The host 12 may subsequently receive from the DUT 14, over the serial link 16, a second pattern as a result of the first action. In response to matching the second pattern to a predefined second pattern stored in the event trigger module 20, the event trigger module 20 may then perform or cause to perform a second action with the external program 22. In one embodiment, the DUT 14 further includes a multiple protocol converter 24, which communicates with a host interface 26. The multiple protocol converter 24 and host interface 26 are inherent to the serial port of the DUT 14 and do not limit or form a necessary part of the disclosed serial protocol-based event trigger.

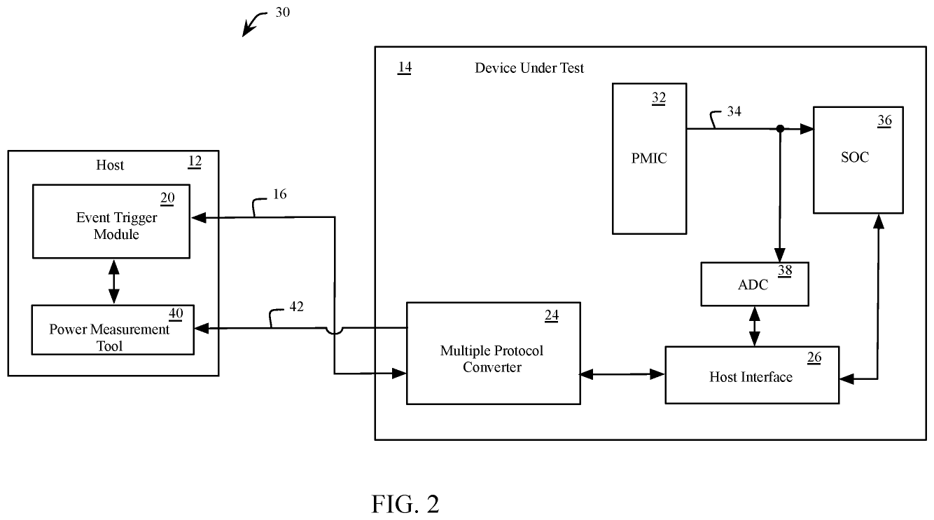

FIG. 2 shows an embodiment 30 of a test system for power measurement. With continued reference to FIG. 1, FIG. 2 shows an example of a condition relating to a power mode of the DUT 14 (e.g., active or deep sleep). The DUT 14 includes a Power Management Integrated Circuit (PMIC) 32 configured to change a supply voltage of the DUT 14, in response to a command from the DUT 14. In one example, the PMIC 32 is used with a Dynamic Voltage and Frequency Scaling (DVFS) to change supply voltages 34, used to power a System-On-a-Chip (SOC) 36. A clock frequency may also be changed by logic internal to the SOC 36 or with another module (not shown) communicating with the SOC 36. The SOC 36 may be controlled by communicating bilaterally with the host 12 using the host interface 26. The DUT 14 may further include an Analog to Digital Converter (ADC) 38 used to measure voltage values of the supply voltages 34 and communicate these measured values to the host interface 26. In the embodiment 30, the multiple protocol converter 24 transmits the measured values over a link 42 (not necessarily a serial link) to a Power Measurement Tool 40 of the host 12. In FIG. 2, the first pattern received over the serial link 16 by the event trigger module 20 (or host) from the DUT 14 is used to confirm a condition of the DUT 14, where the condition is the presence of a PMIC 32. The event trigger module 20 may instruct the PMIC to put the DUT 14 in a deep sleep mode, by sending a command to the DUT 14 over the serial link 16. The second pattern received over the serial link 16 by the event trigger module 20 from the DUT 14 may indicate a successful transition of the DUT 14 to a new frequency and supply voltage. The PMT 40 may then perform the second action to measure or respond to information sent to the PMT 40 over the link 42 by the DUT 14. In one embodiment, the event trigger module 20 operates as a standalone tool. In another embodiment, the event trigger module 20 is configured to perform automated measurements.

In a further example of the embodiment 30 used with DVFS, the event trigger module 12 sends a command to the DUT 14 to enable DVFS. While the DUT 14 is changing a frequency or voltage with the PMIC 32 (e.g., starting DVFS), the event trigger module 20 instructs the PMT 40 to begin capturing data on the link 42. Subsequently, the event trigger module 20 sends another command to the DUT 14 to disable DVFS, instruct the PMT 40 to stop capturing data on the link 42 and set a timestamp so that the plurality of data points captured by the PMT 40 can be correlated in time with the operation of the DUT 14 and analyzed.

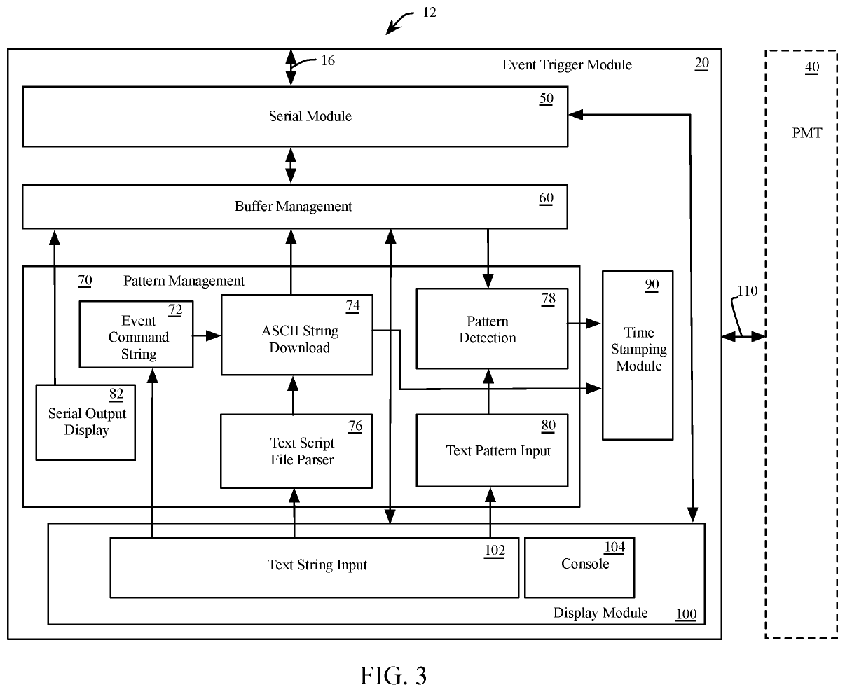

FIG. 3 shows further detail of the embodiment 12 of FIG. 2 of a host-based system for generating a serial protocol-based event trigger. The host 12 includes the event trigger module 20, which communicates with the PMT 40 over a link 110. The event trigger module 20 includes a serial module 50, a buffer management module 60, a pattern management module 70, a timestamping module 90 and a display module 100.

In one embodiment, the serial module 50 includes a Universal Asynchronous Receiver-Transmitter (UART) 50. The serial module 50 communicates with the DUT 14 over the serial link 16 to send commands to the DUT 14 and to receive patterns from the DUT 14.

The serial module 50 communicates with the buffer management module 60 and the display module 100 to display the serialized output from the buffer management module 60 to the display module 100, and to capture information from the display module and send this information to the buffer management module 60. The serial module 50 establishes serial port parameters such as baud rate, parity, stop bits, hardware flow control and software flow control.

In another embodiment, the buffer management module 60 includes an input buffer ring and an output buffer ring. The input buffer ring receives ASCII strings received from the display module 100. The output buffer ring transfers ASCII strings to the display module 100.

In another embodiment, the pattern management module 70 includes an event command string 72, an ASCII string download 74, a text script file parser 76, a pattern detection 78, a text pattern input 80 and a serial output display 82. The event command string 72 receives a command from the display module 100, which is used to affect a condition of the DUT 14. For example, the command may cause the DUT 14 to enter a deep sleep mode, where the condition is a DVFS. The event command string 72 communicates with the ASCII string download 74 to convert the command to an ASCII string, which is subsequently provided to the DUT 14 through the buffer management module 60 and then the serial module 50. The text script file parser 76 converts a plurality of event command strings entered by the user through the display module 100 and sends each parsed event command string to the ASCII string download 74 to be processed and forwarded to the DUT 14 in the same manner as the event command string 72. Commands received by the ASCII string download 74 may also be used to set a timestamp with the time stamping module 90. A pattern detection 78 receives one or more patterns from the DUT 14 through the serial module 50 and buffer management module 60 and compares each pattern to a corresponding predetermined pattern stored in the text pattern input 80 to determine a pattern match. Upon determining a pattern match, the pattern detection 78 may set a timestamp with the time stamping module 90.

The display module 100 includes a text string input 102 and a console 104. In one embodiment, the text string input 102 receives input data entered by a user of the host 12 (e.g., a test operator), or input data from a program automating the operation of the host 12. The input data input to the text string input 102 may be a single command sent to the event command string 72, a plurality of commands sent to the text script file parser 76 or a plurality of command strings, including a conditional command conditioned on an outcome of another command, sent to the text script file parser 76. The text string input 102 may also receive, from a user or automating program, one or more predefined patterns to be sent to the text pattern input 80. The console 104 may display an output from the buffer management module 60, serialized by the serial module 50. The console 104 may also display data received by the text string input 102 from the user or automating program.

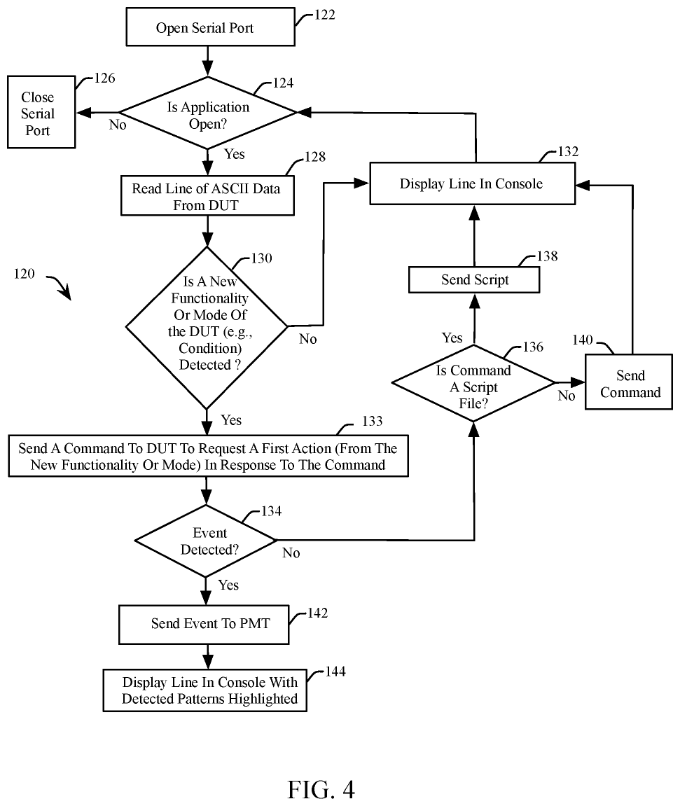

FIG. 4 shows an embodiment 120 of a method for a serial protocol-based event trigger. With continued reference to FIG. 2 and FIG. 3, at 122 a serial port is opened. For example, the serial module 50 defines the baud rate, parity, stop bits and flow control parameters. At 124, a status of an application is verified. In one example, the application is an automating program used to test the DUT 14 in a plurality of modes. At 124, if the application is not verified to be open, the serial port is closed at 126. Otherwise at 128, a line of data is read by from the DUT, by the serial module 50, via a serial port connected to the serial link 16 and buffered by the buffer management module 60. At 130, if a condition is not detected, by performing a pattern match with the pattern detection module 78, then at 132 the line from the serial port is displayed with the console 104 without highlighting, by transferring the line from the buffer management module 60 to the display module 100. For example, an ASCII pattern is not detected in the line of ASCII data read from the DUT 14, hence an absent portion (e.g. the pattern) of the line read from the DUT is not displayed by the console 104 with a font or coloration distinguishing this ASCII text from the remainder of the read line. Otherwise, a command is sent to the DUT 14 at 133 and the event trigger module 20 then determines at 134 if an event has occurred. For example, a command may instruct the DUT 14 to transfer data to a coupled memory device (the “condition”) and the DUT 14 may send a line of ASCII text to the host 12 to indicate an event has occurred, where the event is a successful transfer of data from the DUT 14 to the memory device.

At 134, if an event has not occurred by using the pattern detection module 78 to compare a second pattern (e.g., an ASCII text string) received from the DUT 14 with a predefined second pattern stored in the text pattern input 80, then the embodiment proceeds to 136. At 136, if the command sent to the DUT 14 was from a script file, then the script file is sent to the display module 100 at 138 and displayed with the console 104 at 132. At 136, if the command sent to the DUT 14 was not from a script file, then the command is sent to the display module 100 at 140 and displayed with the console 104 at 132. For example, a line of ASCII text that was sent to the DUT 14, including the command sent at 133, is displayed in the console 104. At 134, if an event is detected to have occurred, then the event is sent to the PMT 40 at 142. In the embodiment 120 of FIG. 4, the condition is the presence of a DVFS capability of the DUT 14, a command instructs the DUT 14 change a frequency or voltage with the detected DVFS capability and the event is a change in a frequency or voltage of the DUT by the PMIC 32, in response to the command. This change is subsequently measured by the PMT 40. For example, at 142, the PMT 40 may then perform the second action to measure or respond to information sent to the PMT 40 over the link 42 by the DUT 14. At 144, the line read at 128 is displayed with the console 104, and the detected patterns from the DUT 14 are also displayed with highlighting. In one embodiment at 144, an output from the PMT 40 is also displayed (e.g., a power or current measurement).

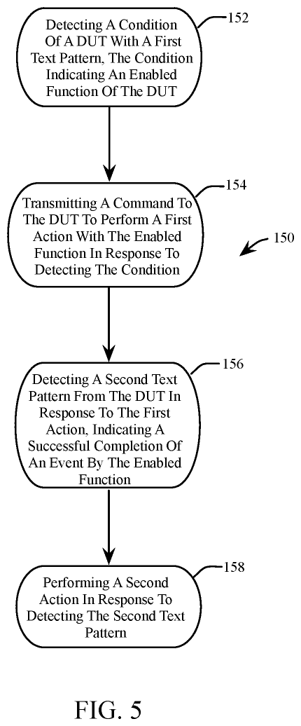

FIG. 5 shows an embodiment 150 of another method for a serial protocol-based event trigger. With continued reference to FIG. 2 and FIG. 3, at 152 a condition of a DUT 14 is detected, wherein the condition comprises a first text pattern. The condition indicates an enabled function of the DUT. For example, the first text pattern received from the DUT 14 is compared with the pattern detection 78 to a predefined first text pattern stored in the text pattern input 80. At 154, a command is transmitted to the DUT 14 to perform a first action with the enabled function in response to detecting the condition. At 156, a second text pattern is detected from the DUT 14 in response to the first action, thereby indicating a successful completion of an event by the enabled function. At 158, a second action is performed in response to detecting the second text pattern.

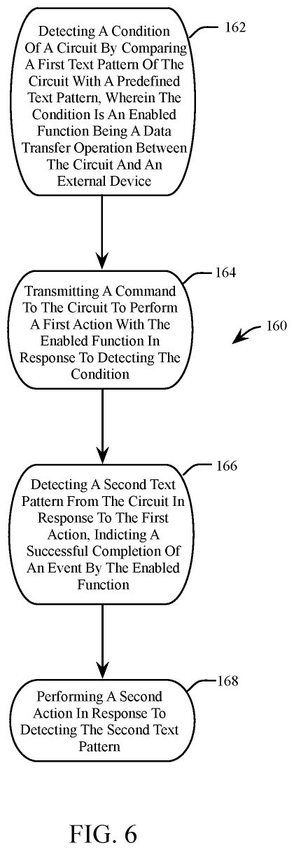

FIG. 6 shows an embodiment 160 of another method for a serial protocol-based event trigger. With continued reference to FIG. 2 and FIG. 3, at 162 a condition of a circuit is detected by comparing a first text pattern of the circuit with a predefined first text pattern. The condition is an enabled function being a data transfer operation between the circuit and an external device. For example, the first text pattern received from the circuit is compared with the pattern detection 78 to a predefined first text pattern stored in the text pattern input 80. At 164, a command is transmitted to the circuit to perform a first action with the enabled function in response to detecting the condition. At 166, a second text pattern is detected from the circuit in response to the first action, thereby indicating a successful completion of an event by the enabled function. At 168, a second action is performed in response to detecting the second text pattern.

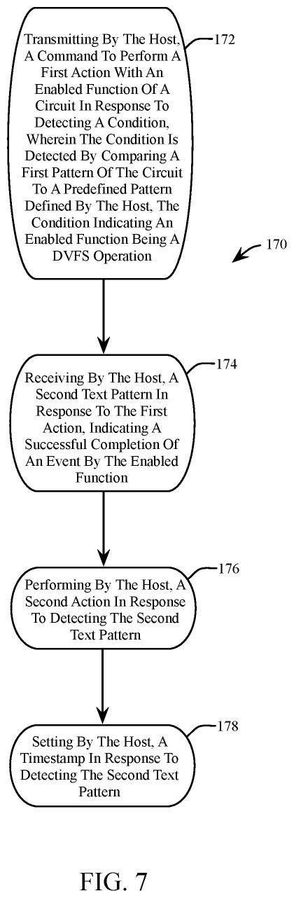

FIG. 7 shows an embodiment 170 of another method for a serial protocol-based event trigger. With continued reference to FIG. 2 and FIG. 3, at 172 a host 12 transmits a command (to a circuit) to perform a first action with an enabled function of the circuit in response to detecting a condition. The condition is detected by comparing a first text pattern of the circuit to a predefined text pattern defined by the host 12. The condition indicates an enabled function being a DVFS operation. At 174, the host 12 receives a second text pattern in response to the first action, indicating a successful completion of an event by the enabled function. At 176, the host 12 performs a second action in response to detecting the second text pattern. At 178, the host 12 sets a timestamp (e.g., with the time stamping module 90) in response to detecting the second text pattern.

As will be appreciated, at least some of the embodiments as disclosed include at least the following. In one embodiment, a method for a serial protocol-based event trigger comprises detecting a condition of a Device Under Test (DUT) with a first text pattern, wherein the condition indicates an enabled function of the DUT. A command is transmitted to the DUT to perform a first action with the enabled function in response to detecting the condition of the DUT. A second text pattern received from the DUT is detected in response to the first action, the second text pattern indicating a successful completion of an event by the enabled function. A second action is performed in response to detecting the second text pattern.

Alternative embodiments of the method for a serial protocol-based event trigger include one of the following features, or any combination thereof. Detecting the condition of the DUT comprises receiving a data from a serial port of the DUT. A timestamp is set in response to detecting the second text pattern. The second action comprises performing an external action external to a host, wherein the host is configured to detect the first text pattern and the second text pattern. A start of the external action is delayed by a delay value. The condition of the DUT comprises a device coupled to the DUT, and the second action comprises a data transfer between the device and the DUT. The condition of the DUT comprises an operating mode of the DUT. The command comprises an event command string. The command comprises a text script file comprising a plurality of event command strings. At least one of the event command strings comprises a conditional operation conditioned on another event command string.

In another embodiment, a method for a serial protocol-based event trigger comprises detecting a condition of a circuit, by comparing a first text pattern generated by the circuit to a predefined text pattern, wherein the condition indicates an enabled function of the circuit, the enable function being a data transfer operation between the circuit and an external device electrically coupled thereto. A command is transmitted to the circuit to perform a first action with the enabled function in response to detecting the condition of the circuit. A second text pattern received from the circuit is detected in response to the first action, the second text pattern indicating a successful completion of an event by the enabled function. A second action is performed in response to detecting the second text pattern.

Alternative embodiments of the method for a serial protocol-based event trigger include one of the following features, or any combination thereof. Detecting the condition of the circuit comprises receiving a data at a first serial port of a host, wherein the first serial port is coupled to a Universal Asynchronous Receiver-Transmitter. An American Standard Code for Information Exchange (ASCII) data string is buffered from the first serial port with a buffer management module. Detecting the condition of the circuit further comprises comparing the first text pattern received from the device with the predefined pattern in a pattern management module, wherein the pattern management module receives the pattern from a text pattern input. A timestamp is set with a timestamping module in response to the pattern matching the predefined pattern. The first text pattern and the second text pattern are displayed with a display module. The external device is a storage device.

In another embodiment, a method for a serial protocol-based event trigger comprises transmitting by a host, a command to perform a first action with an enabled function of a circuit, in response to detecting a condition of a circuit, wherein the condition is detected by comparing a first text pattern generated by the circuit to a predefined text pattern defined by the host, and the condition indicates the enabled function of the circuit, the enabled function being a Dynamic Voltage and Frequency Scaling (DVFS) operation. A second text pattern is received by the host, from the circuit in response to the first action, the second text pattern indicating a successful completion of an event by the enabled function. A second action is performed by the host, in response to detecting the second text pattern. A timestamp is set by the host, in response to detecting the second text pattern.

Alternative embodiments of the method for a serial protocol-based event trigger include one of the following features, or any combination thereof. The enabled function is a voltage scalability of a supply voltage of the circuit using the DVFS operation. The second action comprises performing a voltage measurement of the supply voltage of the circuit.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method for a serial protocol-based event trigger comprising:
detecting a condition of a Device Under Test (DUT) with a first text pattern, wherein the condition indicates an enabled function of the DUT;
transmitting a command to the DUT to perform a first action with the enabled function in response to detecting the condition of the DUT;
detecting a second text pattern received from the DUT in response to the first action, the second text pattern indicating a successful completion of an event by the enabled function; and
performing a second action in response to detecting the second text pattern.

2. The method of claim 1 wherein detecting the condition of the DUT comprises receiving a data from a serial port of the DUT.

3. The method of claim 1 further comprising setting a timestamp in response to detecting the second text pattern.

4. The method of claim 1 wherein the second action comprises performing an external action external to a host, wherein the host is configured to detect the first text pattern and the second text pattern.

5. The method of claim 4 further comprising delaying a start of the external action by a delay value.

6. The method of claim 1 wherein the condition of the DUT comprises a device coupled to the DUT, and the second action comprises a data transfer between the device and the DUT.

7. The method of claim 1 wherein the condition of the DUT comprises an operating mode of the DUT.

8. The method of claim 1 wherein the command comprises an event command string.

9. The method of claim 1 wherein the command comprises a text script file comprising a plurality of event command strings.

10. The method of claim 9 wherein at least one of the event command strings comprises a conditional operation conditioned on another event command string.

11. A method for a serial protocol-based event trigger comprising:
detecting a condition of a circuit, by comparing a first text pattern generated by the circuit to a predefined text pattern, wherein the condition indicates an enabled function of the circuit, the enabled function being a data transfer operation between the circuit and an external device electrically coupled thereto;
transmitting a command to the circuit to perform a first action with the enabled function in response to detecting the condition of the circuit;
detecting a second text pattern received from the circuit in response to the first action, the second text pattern indicating a successful completion of an event by the enabled function; and
performing a second action in response to detecting the second text pattern.

12. The method of claim 11 wherein detecting the condition of the circuit comprises receiving a data at a first serial port of a host, wherein the first serial port is coupled to a Universal Asynchronous Receiver-Transmitter.

13. The method of claim 12 further comprising buffering an American Standard Code for Information Exchange (ASCII) data string from the first serial port with a buffer management module.

14. The method of claim 13 wherein detecting the condition of the circuit further comprises comparing the first text pattern received from the device with the predefined pattern in a pattern management module, wherein the pattern management module receives the pattern from a text pattern input.

15. The method of claim 14 further comprising setting a timestamp with a timestamping module in response to the pattern matching the predefined pattern.

16. The method of claim 11 further comprising displaying the first text pattern and the second text pattern with a display module.

17. The method of claim 11 wherein the external device is a storage device.

18. A method for a serial protocol-based event trigger comprising:
transmitting by a host, a command to perform a first action with an enabled function of a circuit in response to detecting a condition of the circuit, wherein the condition is detected by comparing a first text pattern generated by the circuit to a predefined text pattern defined by the host and the condition indicates the enabled function of the circuit, the enabled function being a Dynamic Voltage and Frequency Scaling (DVFS) operation;
receiving by the host, a second text pattern from the circuit in response to the first action, the second text pattern indicating a successful completion of an event by the enabled function;
performing by the host, a second action in response to detecting the second text pattern; and
setting by the host, a timestamp in response to detecting the second text pattern.

19. The method of claim 18 wherein the enabled function is a voltage scalability of a supply voltage of the circuit using the DVFS operation.

20. The method of claim 19 wherein the second action comprises performing a voltage measurement of the supply voltage of the circuit.
